(19) United States
(12) Patent Application Publication
(10) Pub. No.: US 2014/0188410 A1
(43) Pub. Date: Jul. 3, 2014

(54) Methods for Photovoltaic Performance Disaggregation

(71) Applicants: Shawn Kerrigan, Redwood City, CA (US); Nikhil Rajendra, Stanford, CA (US); Alexander Thornton, San Francisco, CA (US); Matthew Williams, San Francisco, CA (US)

(72) Inventors: Shawn Kerrigan, Redwood City, CA (US); Nikhil Rajendra, Stanford, CA (US); Alexander Thornton, San Francisco, CA (US); Matthew Williams, San Francisco, CA (US)

(73) Assignee: Locus Energy, LLC

(21) Appl. No.: 13/729,066

(22) Filed: Dec. 28, 2012

(51) Int. Cl. G01N 27/00; G06F 17/50; G01R 21/00

(52) U.S. Cl. CPC G01N 27/00; G01R 21/00; G06F 17/50
USPC 702/61; 703/18

(57) ABSTRACT

The present invention provides methods of calibrating photovoltaic model parameters to improve modeling accuracy of photovoltaic power product ion, methods for determining as-built photovoltaic production expectations, methods for determining weather-adjusted photovoltaic performance, methods for determining and quantifying energy losses due to equipment mismatch, methods for determining and quantifying energy losses due to snow, methods for determining and quantifying energy losses due to equipment downtime, methods for determining and quantifying energy losses due to shading, methods for determining and quantifying energy losses due to soiling and equipment degradation.

The present invention relates generally to methods and systems for determining and quantifying energy losses due to many factors, estimating photovoltaic power production, determining as-built photovoltaic production expectations, calibrating photovoltaic model parameters to improve modeling accuracy of photovoltaic power production and disaggregating sources of underperformance in photovoltaic components.

Historical solar power performance may be analyzed by comparing measured energy output against expected energy output on a monthly and yearly basis. This approach fails to provide insight into the drivers of under- or over-performance against expectations such as weather variability, equipment failure and downtime, components mismatch, panel shading, and system degradation. By understanding the sources of deviation from expected production, energy lost from actionable operation and maintenance (O&M) issues can be quantified and the issues remediated if economical, and future energy expectations can be improved for more accurate performance guarantees.

Using power data acquired from revenue grade meters, solar irradiance data from ground sensors, and satellite-modeled irradiance data, systems and methods have been developed to disaggregate the performance of an individual or fleet of photovoltaic systems. These methods may first tune a single-diode photovoltaic model to the specific context (equipment, climate, orientation) of a photovoltaic system, and then create a new expected production baseline using this tuned model with relevant typical meteorological year (TMY) data. Measured weather data (irradiance and cell temperature) may be cleaned and gap-filled to account for shading, soiling, and snow on the sensor. This cleaned weather data may then be processed through the tuned model to quantify the effect of weather conditions on system performance. Statistical methods combined with the tuned photovoltaic model detect and quantify instances of inverter clipping, system downtime, and system shading. The photovoltaic model may be combined with measured data to perform a linear regression on monthly production to determine the rate of degradation.

These and other features, aspects and advantages of the present invention will become better understood with reference to the following description and claims.

### SUMMARY OF THE INVENTION

The present invention relates to a computer processor implemented method of calibrating photovoltaic model parameters to improve modeling accuracy of photovoltaic power production, the method comprising the steps of: obtaining in a computer processor environmental conditions representative of at least one photovoltaic system being analyzed; obtaining in a computer processor measured power of each photovoltaic system being analyzed; estimating by the computer processor a power output for each photovoltaic system being analyzed according to the environmental conditions representative of each photovoltaic system being analyzed to provide a modeled power; comparing by the computer processor the modeled power and the measured power of each photovoltaic system being analyzed to provide a set of ratio data points; filtering by the computer processor the set of ratio data points that are statistical outliers to provide a filtered set of ratio data points; identifying by the computer processor a most statistically representative ratio for the filtered set of ratio data points to provide a calibrated modeled photovoltaic power production.

According to one embodiment of the present invention, a computer implemented method of determining and quantifying energy losses due to equipment mismatch, said method comprising the steps of: obtaining in a computer processor measured power of each photovoltaic system being analyzed; sorting by a computer processor measured power for each photovoltaic system by power output to provide sorted measured power; filtering the sorted measured power by discarding outlier values to provide filtered measured power; obtaining in a computer processor a maximum power output for each photovoltaic system being analyzed; obtaining in a computer processor environmental conditions representative of each photovoltaic system being analyzed; estimating by the computer processor a power output for each photovoltaic system being analyzed according to the environmental conditions representative of each photovoltaic system being analyzed to provide a modeled power; comparing by the computer processor the modeled power and the measured power of each photovoltaic system being analyzed to provide a set of ratio data points; filtering by the computer processor the set of ratio data points that are statistical outliers to provide a filtered data set; identifying by the computer processor a most statistically representative ratio for the filtered data set to provide a calibrated modeled photovoltaic power production; recalculating by the computer processor a power output for each photovoltaic system further according to environmental data as an input to provide weather adjusted photovoltaic performance for the set of ratio data points; determining a set of measured data points in which the measured power is equivalent to an inverter size; subtracting the measured power from the modeled power to quantify power losses due to equipment mismatch; and integrating the power losses due to equipment mismatch over a time period during which the measured power is equivalent to the inverter size.

According to another embodiment of the present invention, A computer implemented method of determining and quantifying energy losses due to snow, said method comprising the steps of: obtaining in a computer processor environmental conditions representative of at least one photovoltaic system being analyzed; obtaining in a computer processor measured power of each photovoltaic system being analyzed; estimating by the computer processor a power output for each photovoltaic system according to the environmental conditions representative of the photovoltaic system being analyzed to provide a modeled power; comparing by the computer processor the modeled power and measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; obtaining in a computer processor measured power and expected typical performance production data; determining a set of time periods from the set of ratio data points where measured power is statistically small compared to expected typical performance production data to provide a set of questioned time periods; verifying snow conditions for the set of questioned time periods to provide a set of verified questioned time periods; subtracting measured power from weather adjusted photovoltaic performance for the set of verified questioned time periods to quantify energy losses due to snow; and integrating the losses due to snow over the verified questions time periods.

According to another embodiment of the present invention, A computer implemented method of determining and quantifying energy losses due to snow, said method comprising the steps of: obtaining in a computer processor environmental conditions representative of at least one photovoltaic system being analyzed; obtaining in a computer processor measured power of each photovoltaic system being analyzed; estimating by the computer processor a power output for each photovoltaic system according to the environmental conditions representative of a photovoltaic system being analyzed to provide a modeled power; comparing by the computer processor the modeled power and measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; obtaining in a computer processor expected typical performance production data for each photovoltaic system; determining a set of time periods from the set of ratio data points where weather adjusted photovoltaic performance is statistically small compared to expected typical performance production data to provide a set of questioned time periods; verifying snow conditions for the set of questioned time periods to provide a set of verified questioned time periods; interpolating between adjacent measured production for the set of ratio data points to the set of data points to provide estimated power for that time; subtracting measured power from estimated power to obtain an estimated power difference; and integrating the estimated power difference over the verified questioned time periods.

According to another embodiment of the present invention, A computer implemented method of determining and quantifying energy losses due to equipment downtime, said method comprising the steps of: obtaining in a computer processor sunrise and sunset for each day of measured production being analyzed for at least one photovoltaic system being analyzed; determining in a computer processor a time after sunrise for each photovoltaic system being analyzed when a measured data is consistently positive to provide a sunrise point for each day; ignoring all zero or negative values after the sunrise point for each day; determining in a computer processor a time before sunset for each photovoltaic system being analyzed when a measured data is not consistently negative to provide a sunset point for each day; ignoring all zero or negative values before the sunset point for each day; determining a set of data points for which measured data is zero or negative between the sunrise point and sunset point; obtaining in a computer processor environmental conditions representative of each photovoltaic system being analyzed; obtaining in a computer processor measured power of each photovoltaic system being analyzed; estimating by the computer processor a power output for each photovoltaic system according to the environmental conditions representative of a photovoltaic system being analyzed to provide a modeled power; comparing by the computer processor the modeled power and the measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; subtracting the measured power from the weather adjusted photovoltaic performance to provide an estimated power difference for that time; and integrating the estimated power difference for that time for a set of data points for which measured data is zero or negative between the sunrise point and sunset point.

According to another embodiment of the present invention, a computer implemented method of determining and quantifying energy losses due to equipment downtime, said method comprising the steps of: obtaining in a computer processor sunrise and sunset for each day of measured production being analyzed for each photovoltaic system being analyzed; determining in a computer processor a time after sunrise for each photovoltaic system being analyzed when the measured data is consistently positive to provide a sunrise point for each day; ignoring all zero or negative values before the sunrise point for each day; determining in a computer processor a time before sunset for each photovoltaic system being analyzed when the measured data is not consistently negative to provide a sunset point for each day; ignoring all zero or negative values after the sunset point for each day; determining a set of data points for which measured data is zero or negative between the sunrise point and sunset point; obtaining in a computer processor environmental conditions representative of a photovoltaic system being analyzed; obtaining in a computer processor measured power of each photovoltaic system being analyzed; estimating by the computer processor a power output for each photovoltaic system according to the environmental conditions representative of each photovoltaic system being analyzed to provide a modeled power; comparing by the computer processor the modeled power and measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; interpolating between adjacent measured production for the set of ratio data points to the set of data points to provide estimated power for that time; subtracting the measured power from the estimated power to obtain an estimated power difference; and integrating the estimated power difference for that time for a set of data points for which measured data is zero or negative between the sunrise point and sunset point.

According to another embodiment of the present invention, a computer implemented method for determining and quantifying energy losses due to shading, said method comprising the steps of: calculating by a computer processor calibrated model parameters; calculating by a computer processor weather adjusted photovoltaic performance for at least one photovoltaic system; determining by a computer processor a set of data points for each photovoltaic system with photovoltaic system equipment mismatch; filtering out the set of data points for each photovoltaic system with photovoltaic system equipment mismatch by the computer processor; determining by a computer processor a subset of data points for each photovoltaic system with snow effects; filtering out the subset of data points for each photovoltaic system with snow effects by the computer processor; determining by a computer processor measured power and weather adjusted photovoltaic production data for each photovoltaic system; dividing by the computer processor the measured power for each photovoltaic system by the weather adjusted photovoltaic performance for each photovoltaic system to obtain a ratio data set having a set of ratios; determining by the computer processor a subset of the ratio data set having a set of ratios where the ratio is less than 1 to identify and provide shading data points; subtracting by the computer processor the measured power from the weather adjusted photovoltaic production data for each photovoltaic system to quantify energy losses; integrate the energy losses over time for each of the shading data points.

According to another embodiment of the present invention, a method of determining and quantifying energy losses due to soiling and equipment degradation, said method comprising the steps of: calculating by a computer processor calibrated model parameters for at least one photovoltaic system; determining by a computer processor a modeled photovoltaic system power using a multivariable linear regression; determining a value for each photovoltaic system capacity by the computer processor using test conditions; iteratively repeating the steps of: determining by a computer processor a modeled photovoltaic system power using a multivariable linear regression; and determining a value for photovoltaic system capacity by the computer processor using test conditions, to determine new photovoltaic capacities for subsequent time periods.

These and other features, aspects and advantages of the present invention will become better understood with reference to the following description and claims.

### BRIEF DESCRIPTION OF THE DRAWINGS

FIG. 1 depicts the present invention;

FIG. 2 depicts the present invention;

FIG. 3 depicts the present invention;

FIG. 4 depicts the present invention;

FIG. 5 depicts the present invention;

FIG. 6 depicts the present invention;

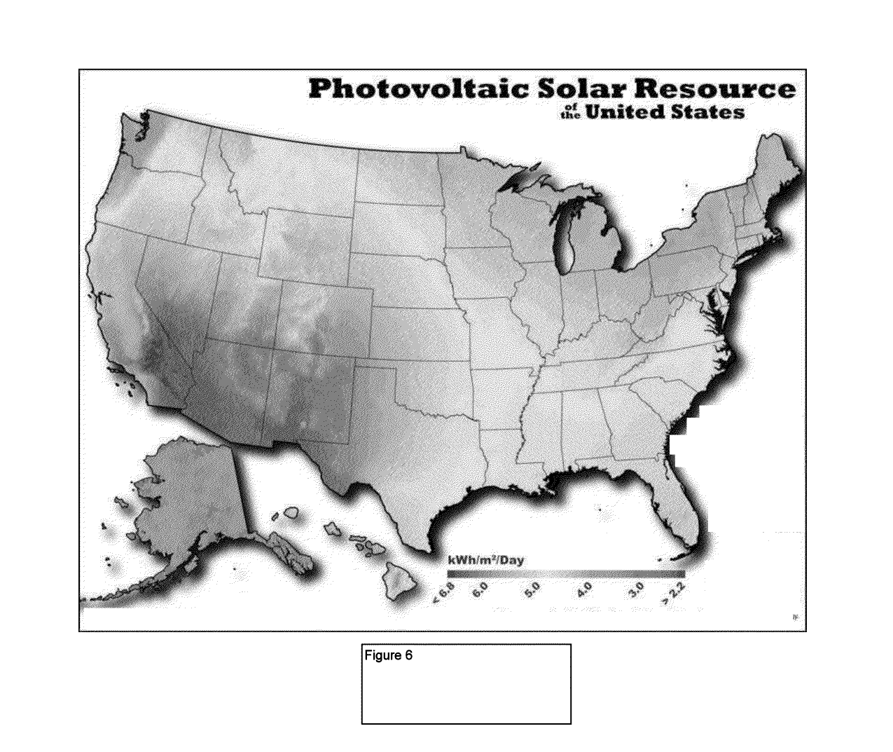

FIG. 7 depicts the present invention;

FIG. 8 depicts the present invention;

FIG. 9 depicts the present invention; and

FIG. 10 depicts the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

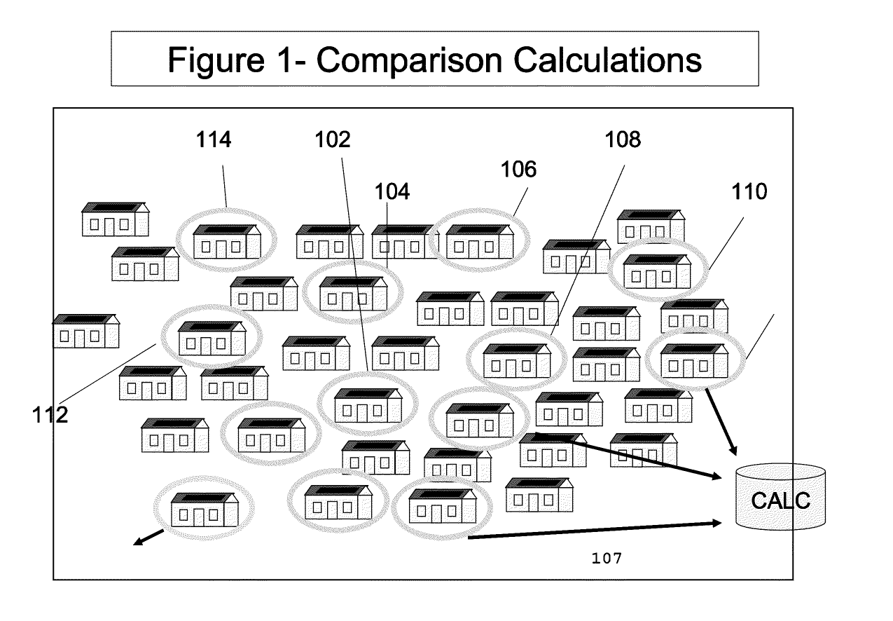

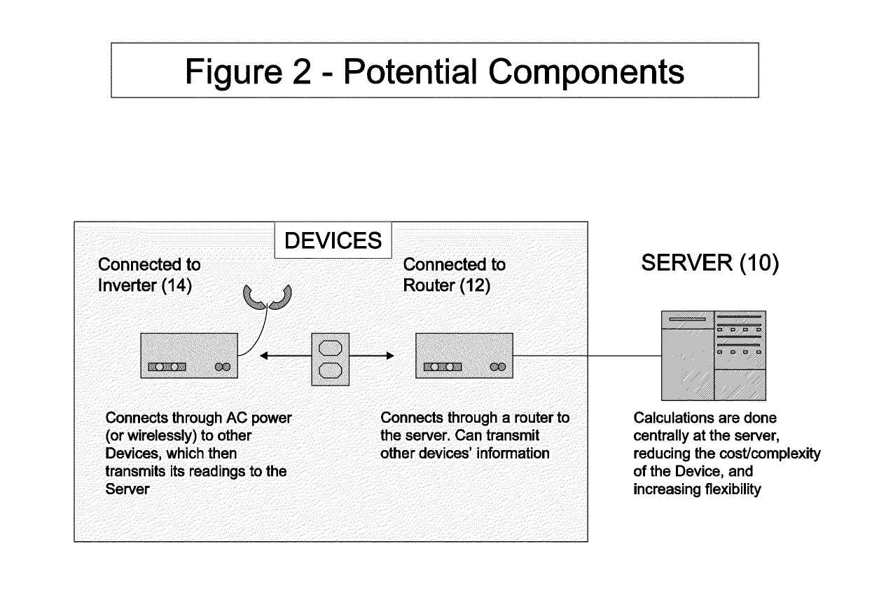

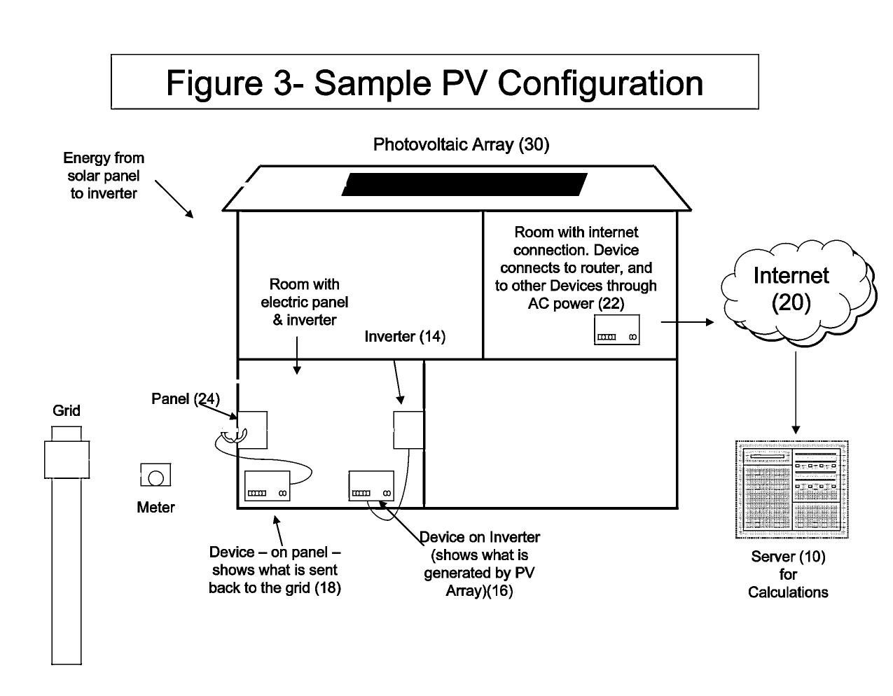

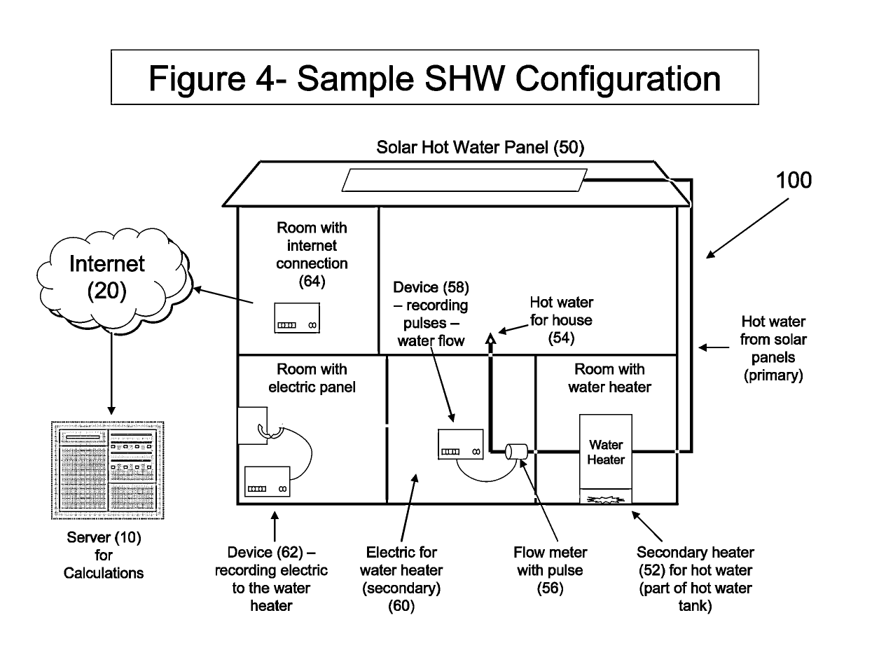

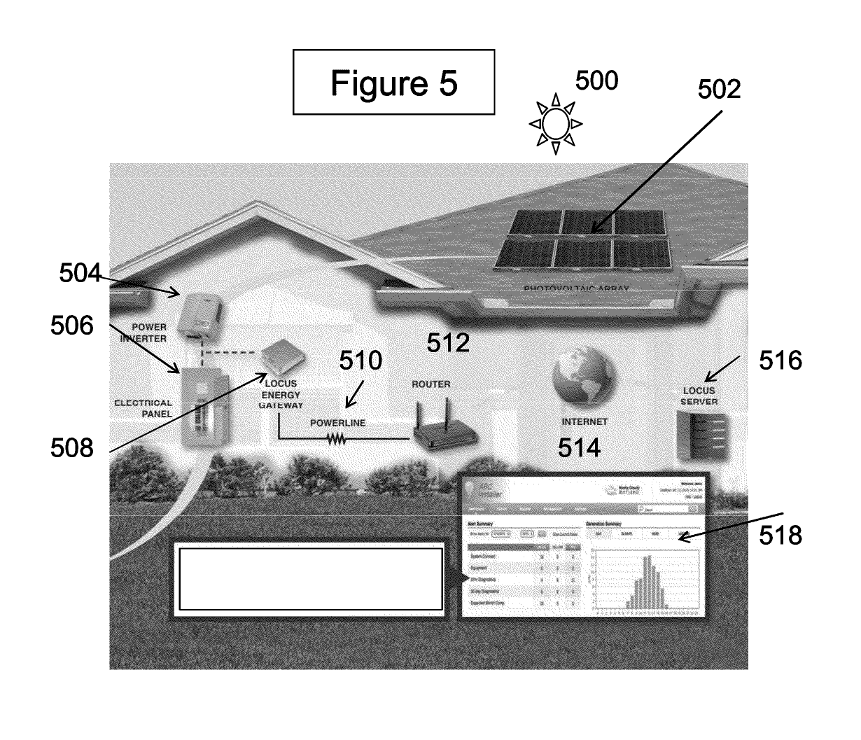

FIGS. 1-5 provide examples of a monitored renewable energy system (more specifically a photovoltaic array solar panel also referred to herein as a solar photovoltaic system or solar powered system) from which information may be obtained. According to the example shown, there is a server 10 and at least one monitored renewable energy system (e.g. 102, 104, 106, 108, 110, 112) which is provided to a user or consumer. There may be at least one data server (10), at least one generation monitoring device (16) in communication with the monitored renewable energy system (at premise monitored renewable energy system (30)) and at least one communication node (22) in communication with at least one of the monitored renewable energy system (30), the generation monitoring device (16) and the data server (10). It should be understood the data server may be a single computer, a distributed network of computers, a dedicated server, any computer processor implemented device or a network of computer processor implemented devices, as would be appreciated by those of skill in the art. The monitored renewable energy system may have background constants that are entered into the system during data setup; populating this part of the data structure is one of the initial steps to the process. During this time, all required (or potentially required) background information may be loaded into the system. This data will later be used for system calculations and diagnostics. Background constants may include: (1) Full Calendar with sunrise and sunset according to latitude throughout the year; (2) Insolation or ‘incident solar radiation’: This is the actual amount of sunlight falling on a specific geographical location. There are expected amounts of radiation which will fall on an area each day, as well as an annual figure. Specific Insolation is calculated as kWh/m2/day. The importance of this variable is that it can combine several other Background Constants; and (3) Location Functionality. It is envisioned that some of this information may be input and some may be determined automatically. The proximity of each system to each other system may be determined, and forms a part of the methods used to determine the geographic average of the renewable energy systems. While there are different specific methods of implementing Location Functionality, generally this relies on a large database of locations which are tied to zones. Because the relational distances between the zones are stored within the software, the distances between any two locations can then be easily and accurately calculated.

The term production data refers to any data that is received from the photovoltaic system and/or solar irradiance sensor. The energy generated by each monitored renewable energy system and/or solar irradiance sensor is recorded as production data and the data server may then determine comparative information based upon at least one of the background constant, the diagnostic variable, the system coefficient and the energy generated to determine a comparative value of the monitored renewable energy system. The term comparative value is intended to include any value that compares one system to another system or a group of systems. For example, this may be as simple as an “underperforming” designation when the system's performance is less than another system or group of systems performance in terms of power generated.

A sample system may have at least one inverter (14) in communication with the monitored renewable energy system (e.g. 50, 30). The inverter (14) is an electronic circuit that converts direct current (DC) to alternating current (AC). There may also be at least one return monitor (18) determining the energy returned to a grid by the at-least one monitored renewable energy system. At least one background constant may be determined and saved in the data server(s). The monitored renewable energy system (e.g. 30, 50) may be at least partially powered by at least one alternate energy source. There may be at least one generation monitoring device (e.g. 58), which calculates the energy generated at each consumer's premises by the monitored renewable energy system (e.g. 30, 50); at least one communication node (64) in communication with each at least one generation monitoring device (e.g. 58); at least one data server (10) in communication with communication node (e.g. 64), wherein the data server(s) (10) accept information from the communication node (e.g. 64) to determine the power generated at a first user's premises (100) and compare the power generated at a first user's premises (100) to Comparative Information obtained from at least two monitored renewable energy systems (e.g. 102, 104, 106, 108, 110, 112, 114) to determine if the first user's monitored renewable energy system (100) is within a predetermined deviation from the comparative information. This may provide a comparative value. The communication node may be further comprising a data storage means for storing usage information. For example, the communication node (64) may be a computer with a hard drive that acts as a data storage means for storing usage information. The generation monitoring device may be selected from the group consisting of pulse meter, temperature meter, electromechanical meter, solid state meter, flow meter, electric meter, energy meter and watt meter. There may also be at least one return monitoring device in communication with the inverter which calculates the energy returned to a grid by the system.

The monitored renewable energy system may be, for example, a solar system, solar panel system, photovoltaic, thermal, wind powered, geothermal, hydropower. A secondary energy source (e.g. 52) may be in communication with and at least partially powering the monitored renewable energy system. It should be understood, though, this is only for ancillary power in the event that the renewable energy source (50) is not capable of entirely powering the at premise monitored renewable energy system.

The generation monitoring device may be any type of meter, by way of example, this may include a pulse meter, temperature meter, electromechanical meter, solid state meter, flow meter, electric meter, energy meter and watt meter. An installation will have a communication node or hub set up at the location with the system. One of the communication nodes may act as a hub. These devices connect to the internet and send the data collected by the nodes to the Server. They have the following properties: The hub has a web server and connects to a standard internet connection (Ethernet). It does not require a computer or other device to make this connection. Each hub has its own unique IP or DNS address. The hub is configured by a web browser. The web browser allows the hub to have specific nodes assigned to it. This set up feature will allow another hub in the area to be set up with its own nodes so that all can operate wirelessly without disruption. Also, the hub is able to configure specific aspects of the hub, such as the connection with the server, data recording and time settings and the ability to configure the attached nodes, including their recording properties.

Each installation may have two or more Data Nodes. These are typically connected wirelessly to the Hub, and connected directly to the inputs/outputs from the Solar Hot Water system. They communicate constantly with the Hub, transferring data which the Hub then sends up to the server. They may have the following properties: The first Required Node connects to a flow meter attached to the Water Tank that is connected to the Solar Hot Water system. This Node will operate as a pulse meter, ‘clicking’ whenever a unit (either a gallon or a liter) of hot water passes from the tank. The second Required Node connects to either the electric panel at the switch for the Hot Water tank's electric power OR to a flow/other meter for gas/oil to the secondary heater for the Hot Water tank. The Node may have a data storage means for storing flow/usage information. Together, the data gathered from these Required Node connections allow the software on the serve to convert the utilized hot water into an accurate reading of utilized solar energy by subtracting the energy required to by the secondary heating mechanism. The term utilized generation refers to the energy generated by the at-premise power system, less any energy that has not been consumed by the at premise power system (e.g. the energy used to heat water that remains in the tank and is not subsequently used). Note that the term “at-premise power system” is one type of monitored renewable energy system, as claimed. There may also be other Nodes, which may be used to measure other aspects of the system and gain even more accurate readings. For example: the temperature of the hot water on an ongoing basis. The system may be monitored from a remote location (such as a computer in a different location).

The components node (100), hub (102) and server (10) make up the required core components needed to accurately measures the actual usable output from a Solar Hot Water (SHW) system. Essentially, the hub (102) connects to multiple nodes (100) which simultaneously measure the secondary power going into the system along with the hot water going out. Controlling for any background power requirements (e.g. for pumping), it can measure the usable BTUs created by solar by analyzing the measurements at the server (104) level.

Before installing a photovoltaic system in a given location, an estimate of performance expectations is created considering the locational context, typical climate and proposed equipment. Performance expectation estimates also employ assumptions regarding factors that could reduce performance, such as shading, equipment mismatch, and soiling. Properly choosing these assumptions is one of the more difficult aspects of system modeling. Measured performance of an installed system is often compared against the performance expectations to understand if a photovoltaic system is functioning properly.

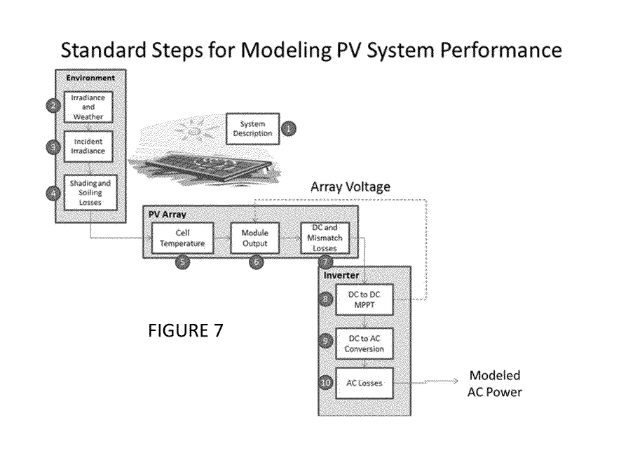

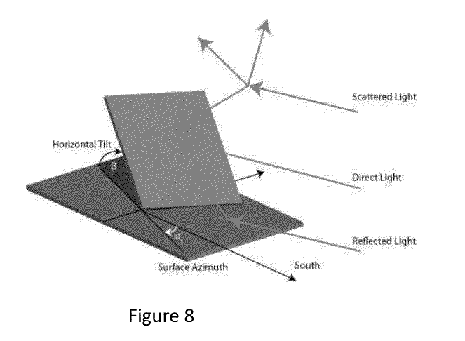

Over the short term, weather volatility is the primary driver of uncertainty. However, weather volatility should decrease to align with TMY expectations as the photovoltaic system approaches its lifetime. A photovoltaic system converts sunlight to electrical energy through many steps, as shown in FIG. 7. A PV model follows the same steps to mimic the physical processes. The numbered list below corresponds to the numbers in the figure. System Description: System description information is entered by the user and defines the parameters used within the model. This information includes location, system orientation, PV panel manufacturer and model and Inverter manufacturer and model. Location is provided as latitude and longitude, and is essential for understanding the positioning of the sun based on the date and time. The system orientation may be determined according to panel tilt and azimuth, as shown in FIG. 8. The panel orientation is necessary in understanding the angle of incident light to properly calculate incident irradiance (as described below). Each PV panel is unique in its technical properties and characteristics making the PV panel manufacturer and model important system information. PV panel parameters used in the model include: A_{c}: surface area of the PV panel [m²]; I_{mp,ref}: current at maximum power point at STC (standard test conditions) [A]; V_{mp,ref}: voltage at maximum power point at STC [A]; T_{NOCT}: nominal operating cell temperature [° C.]; Rₛ: series resistance [Ω]; R_{sh,ref}: shunt resistance at STC [Ω]; I_{L,ref}: photoelectric light current at STC [A]; I_{o,ref}: diode reverse saturation current at STC [A]; a_{ref}: ideality factor parameter at STC [eV]; I_{sc,ref}: Short circuit current at STC [A]; V_{oc,ref}: Open circuit voltage at STC [V]; α_{sc}: temperature coefficient for short circuit current [A/° C.]; β_{oc}: temperature coefficient for open circuit voltage [V/° C.].

It is also important to obtain Inverter manufacturer and model: Each inverter is unique in its technical properties and characteristics. Inverter parameters used in the model include: V_{AC}: defined output voltage [V]; P_{aco}: maximum AC power [W_{AC}]; P_{dco}: DC power input for maximum AC power [W_{DC}]; Pₛₒ: minimum DC power required for inversion [W_{DC}]; C₀: parameter defining the curvature (parabolic) of the relationship between ac-power and dc-power at the reference operating condition, default value of zero gives a linear relationship [1/W]; C₁: empirical coefficient allowing P_{dco} to vary linearly with dc-voltage input, default value is zero [1/V]; C₂: empirical coefficient allowing Pₛₒ to vary linearly with dc-voltage input, default value is zero [1/V]; C₃: empirical coefficient allowing Cₒ to vary linearly with dc-voltage input, default value is zero.

Irradiance and weather data can be obtained from one of several different sources. For larger scale systems, weather stations are installed on-site. These weather stations can measure either plane-of-array irradiance or GHI (global horizontal irradiance). Plane of array is irradiance incident on the same plane as the PV array, while GHI is irradiance incident on a flat plane (not tilted). Panel temperature is also often provided. Virtual Irradiance: Virtual Irradiance provides GHI, DNI (direct normal irradiance) and DHI (direct horizontal irradiance) at 30 minute intervals. National weather stations: These weather stations provide ambient temperature and wind speed for when cell temperature is not available. Typical meteorological year (TMY) data provides a representative year for the purposes of solar production estimates. This information includes GHI, DNI, DHI, ambient temperature, and wind speed.

For Incident Irradiance data, if plane of array irradiance is provided, it is accepted as incident irradiance. If not, the solar angle of incidence is calculated using solar geometric algorithms based on system location, orientation, date, and time. Using this angle of incidence with GHI, DNI, and DHI will result in incident irradiance.

Shading and soiling losses reduce the incoming incident irradiance that strikes the PV panel. Cell temperature is either directly measured by a weather station on site, or calculated using incident irradiance, ambient temperature, and wind speed.

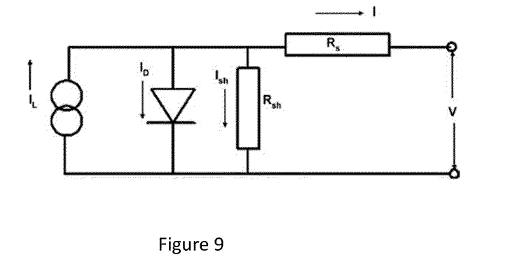

The PV model is based on the single diode model (aka 5-parameter model). This model represents the functioning of a PV cell in terms of a simple electric circuit, shown in FIG. 9 Error! Reference source not found. I_{L}: incoming photoelectric current; I_{D}: diode reverse saturation current; Iₛₕ: shunt current; Rₛₕ: shunt resistance; Rₛ: series resistance; I: output current; V: output voltage. The model assumes operation as maximum power point. Maximum power is labeled as Pₘₐₓ in the figure below. DC and Mismatch Losses: DC losses include the losses occurring in the wiring and connection between PV panels prior to reaching the inverter input. Mismatch losses are due to panels differing slightly in power output. When connected in a series, the lowest producing panel reduces the overall output of the string. DC to DC MPPT (maximum power point tracking): This conversion is automatically calculated in the Module Output step. In physical reality, the inverter controls the optimization of DC output of panels. The present invention simplifies this and skips this step. DC to AC conversion is calculated through the inverter model. This is an empirically derived model found to balance minimal laboratory testing with high accuracy. AC Losses: AC losses are those occurring due to wiring and transformations on the AC side prior to arriving at the power meter.

The present invention provides a methodology for disaggregating photovoltaic system performance by iterating through steps of cleaning and filtering data. Each step filters out the effect of one driver of photovoltaic performance so that each driver can be independently and accurately identified and quantified. Once the effect of a performance driver is determined, the data is cleaned to compensate for that effect. Further performance drivers are found iteratively by repeating the analysis and cleaning steps. The Methodology is comprised of the following: background variables, input parameters and logic based on those variables parameters.

MEASURED ENVIRONMENTAL DATA: Environmental conditions, such as irradiance, photovoltaic cell temperature, ambient air temperature, wind speed, precipitation, general weather conditions, and time, measured by environmental sensors. Environmental sensors include, but are not limited to, solar irradiance sensors, wind sensors, and temperature sensors.

MODELED ENVIRONMENTAL DATA: Environmental conditions, such as irradiance, photovoltaic cell temperature, ambient air temperature, wind speed, precipitation, general weather conditions, and time, modeled by using computational algorithms and available input data. Available input data can include but not be limited to satellite imagery, aggregated photovoltaic power production, and distributed irradiance measurements.

ENVIRONMENTAL SENSOR NETWORK FEED: This is a feed providing data obtained from a network of environmental sensors. The feed includes environmental conditions, location, and time among other variables. Environmental sensors include, but are not limited to, solar irradiance sensors, wind sensors, and temperature sensors.

RENEWABLE ENERGY PROJECT NETWORK FEED: This is a feed providing data obtained from a network of renewable energy projects. The feed includes individual system level energy production, location, and time among other variables. Renewable energy systems include, but are not limited to, solar power systems and wind power systems.

PV MODEL: A PV model converts environmental data input into an estimate for AC power production from a photovoltaic system.

SOLAR POSITION CALCULATIONS: These are theoretical formulas for calculating the position of the sun and solar noon among other variables based on astronomical research.

SUNRISE AND SUNSET CALCULATIONS: Formulas which leverage solar position calculations to obtain the precise time of sunrise and sunset for a specific geographic location for a given date.

ASTM E2848-11 STANDARD TEST METHOD FOR REPORTING PHOTOVOLTAIC NON-CONCENTRATOR SYSTEM PERFORMANCE: This test method provides measurement and analysis procedures for determining the capacity of a specific photovoltaic system built in a particular place and in operation under natural sunlight.

ITERATIVE DATA CLEANING: A repeatable process of compensating for the effects of a performance driver once identified, and then using the cleaned data for further identification and quantification of performance drivers.

One aspect of the present invention provides a method for calibrating photovoltaic model parameters to improve modeling accuracy of photovoltaic power production.

This approach calibrates photovoltaic model parameters to the specific context of the photovoltaic installation being analyzed. These model parameters account for physical factors that are external to the electrical characteristics simplified by the photovoltaic model. This calibration process works for both ground-based irradiance sensors, as well as satellite-modeled irradiance.

Definition of Variables. Measured environmental conditions=weather measurements obtained with physical sensors installed at the location of the photovoltaic system being analyzed. Modeled environmental conditions=weather estimates obtained with computational models. Statistical outliers=values that are outside reasonable bounds for a specific photovoltaic system. The bounds can be but are not always defined by using standard deviation of the data set. Statistically representative ratio=the value that minimizes error of modeled power vs. measured power. This value can be but is not always the median, mean or mode of a set of ratios. By way of example, the “most statistically representative ratio” may be found by filtering out any data points that are not within ½ standard deviation (roughly +/−17%) of the median to create a subset and take the mean of the subset to provide the most statistically representative ratio.

The method may be summarized as follows: (1) Obtain measured or modeled environmental conditions representative of those experienced by the photovoltaic system being analyzed; (2) Using the environmental conditions from step 1 as input, estimate photovoltaic system power output; (3) Compare modeled power with measured power, obtaining a ratio of modeled divided by measured; (4) Filter out ratio data points that are statistical outliers; (5) Identify the most statistically representative ratio for the data set, taken as the model parameter correction factor.

More specifically, a computer processor implemented method of calibrating photovoltaic model parameters to improve modeling accuracy of photovoltaic power production is provided. The method comprising the steps of: obtaining in a computer processor environmental conditions representative of at least one photovoltaic system being analyzed; obtaining in a computer processor measured power of each photovoltaic system being analyzed; estimating by the computer processor a power output for each photovoltaic system being analyzed according to the environmental conditions representative of each photovoltaic system being analyzed to provide a modeled power; comparing by the computer processor the modeled power and the measured power of each photovoltaic system being analyzed to provide a set of ratio data points; filtering by the computer processor the set of ratio data points that are statistical outliers to provide a filtered set of ratio data points; and identifying by the computer processor a most statistically representative ratio for the filtered set of ratio data points to provide a calibrated modeled photovoltaic power production. The environmental conditions may be measured environmental conditions or modeled environmental conditions. The most statistically representative ratio for the filtered set of ratio data points may be taken as the model parameter correction factor.

The present invention also provides methods for determining as-built photovoltaic production expectations. This approach generates energy performance expectations by using typical meteorological year (TMY) data as input to a photovoltaic model with calibrated model parameters. The calibrated model parameters account for the physical realities of the as-built system. The resulting energy output can be used as photovoltaic production expectations for the lifetime of the system.

Definition of Variables._TMY=Typical Meteorological Year.

There may also be the step of estimating by the computer processor a photovoltaic production expectation for each photovoltaic system according to typical meteorogical year (TMY) data as an input. This may be performed by: (1) Calculating calibrated model parameters (above, Method for calibrating photovoltaic model parameters to improve modeling accuracy of photovoltaic power production); and (2) using TMY data as an input into the calibrated PV model.

According to another aspect of the present invention, methods for determining weather-adjusted photovoltaic performance as provided. This approach estimates weather-independent photovoltaic performance for a given time period. The resulting performance estimate is useful in isolating underperformance issues unrelated to variable weather input.

Definition of Variables. Production expectations=expected electric energy produced for a given time period using typical meteorological year (TMY) data. Measured environmental conditions=weather measurements obtained with physical sensors installed at the location of the photovoltaic system being analyzed. Modeled environmental conditions=weather estimates obtained with computational models

The methods for determining weather-adjusted photovoltaic performance are generally according to the steps of: (1) Calculating calibrated model parameters (above, Methods for calibrating photovoltaic model parameters to improve modeling accuracy of photovoltaic power production); (2) calculating as-built photovoltaic production expectations (above, Methods for determining as-built photovoltaic production expectations); and (3) For the same time period as the production expectations, use measured or modeled environmental data as input to the calibrated PV model. Specifically, the step of estimating by the computer processor a power output for the photovoltaic system may be further according to measured environmental data as an input to provide weather adjusted photovoltaic performance or the step of estimating by the computer processor a power output for each photovoltaic system may be further according to modeled environmental data as an input to provide weather adjusted photovoltaic performance. The term “weather adjusted photovoltaic performance” is calibrated modeled power with environmental data as the input.

According to another aspect of the present invention, methods for determining and quantifying energy losses due to equipment mismatch are provided. This approach identifies and quantifies losses due to mismatches between the photovoltaic array and inverter sizes.

Definition of Variables. Inverter=hardware device that converts direct current (DC) electricity to alternating current (AC) electricity. Inverter size=the rated AC power output of the inverter. Measured production data=measured power of a photovoltaic system. Outlier threshold=a set value that determines whether a certain data point should be filtered out of the analysis set. This value may be found using standard deviation or a certain proportion of the previously found maximum value.

The methods for determining and quantifying energy losses due to equipment mismatch may be generally summarized as: (1) Sorting measured production data by power output; (2) filtering outliers by discarding values that only occur once or exceed a set outlier threshold; (3) Obtaining the maximum power output; (4) Calculating calibrated model parameters (above, methods for calibrating photovoltaic model parameters to improve modeling accuracy of photovoltaic power production); (5) Calculating weather-adjusted photovoltaic performance (above, methods for determining weather-adjusted photovoltaic performance); (5) To quantify losses, subtracting measured production from weather-adjusted photovoltaic performance for all points that the measured production data is equivalent to the inverter size. Then, integrate over the time period during which measured production is equivalent to inverter size.

More specifically, a computer implemented method of determining and quantifying energy losses due to equipment mismatch, may be according to the steps of: obtaining in a computer processor measured power of each photovoltaic system being analyzed; sorting by a computer processor measured power for each photovoltaic system by power output to provide sorted measured power; filtering the sorted measured power by discarding outlier values to provide filtered measured power; obtaining in a computer processor a maximum power output for each photovoltaic system being analyzed; obtaining in a computer processor environmental conditions representative of each photovoltaic system being analyzed; estimating by the computer processor a power output for each photovoltaic system being analyzed according to the environmental conditions representative of each photovoltaic system being analyzed to provide a modeled power; comparing by the computer processor the modeled power and the measured power of each photovoltaic system being analyzed to provide a set of ratio data points; filtering by the computer processor the set of ratio data points that are statistical outliers to provide a filtered data set; identifying by the computer processor a most statistically representative ratio for the filtered data set to provide a calibrated modeled photovoltaic power production; recalculating by the computer processor a power output for each photovoltaic system further according to environmental data as an input to provide weather adjusted photovoltaic performance for the set of ratio data points; determining a set of measured data points in which the measured power is equivalent to an inverter size; subtracting the measured power from the modeled power to quantify power losses due to equipment mismatch; and integrating the power losses due to equipment mismatch over a time period during which the measured power is equivalent to the inverter size.

According to another aspect of the present invention, methods for determining and quantifying energy losses due to snow is provided. This approach identifies and quantifies losses due to snow accumulation on the photovoltaic panels and any on-site weather sensor.

Definition of Variables. Statistically small=much smaller than the comparison such that there is a very low probability (−1%) that the value could fit within the comparison data set. By way of example, “statistically small” may be any data point that is greater than 2 standard deviations below the median. Weather data feeds=sources of historical weather data. This weather data generally includes temperature, humidity, wind speed, and precipitation. Snow conditions=snow precipitation which accumulates on photovoltaic panels and block incoming sunlight.

The method for determining and quantifying energy losses due to snow may be generally according to the steps of: (1) Using measured production data, determining time periods where measured energy production and/or weather-adjusted photovoltaic performance are statistically small compared to the typical and performance expectations for this time period; (2) For the time period in question, use weather data feeds to verify for snow conditions; (3) Calculate calibrated model parameters (above, Methods for calibrating photovoltaic model parameters to improve modeling accuracy of photovoltaic power production); (4) Calculate weather-adjusted photovoltaic performance (above, Methods for determining weather-adjusted photovoltaic performance); (5) To quantify losses, subtract measured production from weather-adjusted photovoltaic performance using modeled environmental conditions for all points that the snow conditions have been identified. (6) Then, integrate over the time period during which there were snow conditions.

More specifically, a computer implemented method of determining and quantifying energy losses due to snow is provided, the method comprising the steps of: obtaining in a computer processor environmental conditions representative of at least one photovoltaic system being analyzed; obtaining in a computer processor measured power of each photovoltaic system being analyzed; estimating by the computer processor a power output for each photovoltaic system according to the environmental conditions representative of the photovoltaic system being analyzed to provide a modeled power; comparing by the computer processor the modeled power and measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; obtaining in a computer processor measured power and expected typical performance production data; determining a set of time periods from the set of ratio data points where measured power is statistically small compared to expected typical performance production data to provide a set of questioned time periods; verifying snow conditions for the set of questioned time periods to provide a set of verified questioned time periods; subtracting measured power from weather adjusted photovoltaic performance for the set of verified questioned time periods to quantify energy losses due to snow; and integrating the losses due to snow over the verified questions time periods.

Another method of determining and quantifying energy losses due to snow, is according to the steps of: obtaining in a computer processor environmental conditions representative of at least one photovoltaic system being analyzed; obtaining in a computer processor measured power of each photovoltaic system being analyzed; estimating by the computer processor a power output for each photovoltaic system according to the environmental conditions representative of a photovoltaic system being analyzed to provide a modeled power; comparing by the computer processor the modeled power and measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; obtaining in a computer processor expected typical performance production data for each photovoltaic system; determining a set of time periods from the set of ratio data points where weather adjusted photovoltaic performance is statistically small compared to expected typical performance production data to provide a set of questioned time periods; verifying snow conditions for the set of questioned time periods to provide a set of verified questioned time periods; interpolating between adjacent measured production for the set of ratio data points to the set of data points to provide estimated power for that time; subtracting measured power from estimated power to obtain an estimated power difference; and integrating the estimated power difference over the verified questioned time periods.

According to another aspect of the present invention, methods for determining and quantifying energy losses due to equipment downtime are provided. This approach identifies and quantifies losses due to equipment downtime resulting from hardware failure, system maintenance or other events that would completely impede photovoltaic system production.

Definition of Variables. Sunrise and sunset calculations=equations used to determine the precise time of sunrise and sunset for a given geographic location. Consistently positive=steady-state set of positive values, which can generally considered to be above a certain minimum threshold and increasing in nature. The purpose of checking for consistently positive values is to filter out start of day and end of day transients.

Generally, the methods for determining and quantifying energy losses due to equipment downtime may be according to the steps of: (1) For each day of measured production being analyzed, calculate sunrise and sunset times; (2) After sunrise, find the corresponding time for when the measured data is consistently positive. Ignore all zero or negative values prior to this time for this day; (3) Just before sunset, find the corresponding time for when the measured data stops being consistently negative. Ignore all zero or negative values after this time for this day; (4) Find each point for which measured data is zero or negative between the times found in steps 2 and 3. (5) Calculate calibrated model parameters (above, methods for calibrating photovoltaic model parameters to improve modeling accuracy of photovoltaic power production); (6) Calculate weather-adjusted photovoltaic performance (above, methods for determining weather-adjusted photovoltaic performance); (7) For each data point, compare with weather-adjusted photovoltaic performance or interpolate between adjacent measured production to obtain the estimated power for that time; and (8) Integrate over time for each of the data points found to quantify losses.

More specifically, a computer implemented method of determining and quantifying energy losses due to equipment downtime is provided, the method comprising the steps of: obtaining in a computer processor sunrise and sunset for each day of measured production being analyzed for at least one photovoltaic system being analyzed; determining in a computer processor a time after sunrise for each photovoltaic system being analyzed when a measured data is consistently positive to provide a sunrise point for each day; ignoring all zero or negative values after the sunrise point for each day; determining in a computer processor a time before sunset for each photovoltaic system being analyzed when a measured data is not consistently negative to provide a sunset point for each day; ignoring all zero or negative values before the sunset point for each day; determining a set of data points for which measured data is zero or negative between the sunrise point and sunset point; obtaining in a computer processor environmental conditions representative of each photovoltaic system being analyzed; obtaining in a computer processor measured power of each photovoltaic system being analyzed; estimating by the computer processor a power output for each photovoltaic system according to the environmental conditions representative of a photovoltaic system being analyzed to provide a modeled power; comparing by the computer processor the modeled power and the measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; subtracting the measured power from the weather adjusted photovoltaic performance to provide an estimated power difference for that time; and integrating the estimated power difference for that time for a set of data points for which measured data is zero or negative between the sunrise point and sunset point.

According to another aspect of the present invention, a computer implemented method of determining and quantifying energy losses due to equipment downtime is provided, the method comprising the steps of: obtaining in a computer processor sunrise and sunset for each day of measured production being analyzed for each photovoltaic system being analyzed; determining in a computer processor a time after sunrise for each photovoltaic system being analyzed when the measured data is consistently positive to provide a sunrise point for each day; ignoring all zero or negative values before the sunrise point for each day; determining in a computer processor a time before sunset for each photovoltaic system being analyzed when the measured data is not consistently negative to provide a sunset point for each day; ignoring all zero or negative values after the sunset point for each day; determining a set of data points for which measured data is zero or negative between the sunrise point and sunset point; obtaining in a computer processor environmental conditions representative of a photovoltaic system being analyzed; obtaining in a computer processor measured power of each photovoltaic system being analyzed; estimating by the computer processor a power output for each photovoltaic system according to the environmental conditions representative of each photovoltaic system being analyzed to provide a modeled power; comparing by the computer processor the modeled power and measured power of each photovoltaic system being analyzed to provide a set of ratio data points; filtering by the computer processor the set of ratio data points that are statistical outliers; identifying by the computer processor a most statistically representative ratio for the data set to provide a calibrated modeled photovoltaic power production; recalculating by the computer processor a power output for each photovoltaic system further according to environmental data as an input to provide weather adjusted photovoltaic performance for the set of ratio data points; interpolating between adjacent measured production for the set of ratio data points to the set of data points to provide estimated power for that time; subtracting the measured power from the estimated power to obtain an estimated power difference; and integrating the estimated power difference for that time for a set of data points for which measured data is zero or negative between the sunrise point and sunset point.

The present invention provides methods for determining and quantifying energy losses due to shading. This approach identifies and quantifies losses due to shading of the photovoltaic array.

Definition of Variables. Statistically less than 1=outside of a statistical threshold around 1. This can be but is not always related to the standard deviation of the data set.

The methods for determining and quantifying energy losses due to shading may be generally according to: (1) Calculate calibrated model parameters (above, method for calibrating photovoltaic model parameters to improve modeling accuracy of photovoltaic power production); (2) Calculate weather-adjusted photovoltaic performance (above, method for determining weather-adjusted photovoltaic performance); (3) Determine and filter out data points with equipment mismatch (above, method for determining and quantifying energy losses due to equipment mismatch); (4) Determine and filter out data points with snow effects (above, method for determining and quantifying energy losses due to snow); (5) Determine and filter out data points with shading (above, method for determining and quantifying energy losses due to shading); (6) Divide measured production data by weather-adjusted photovoltaic production data to obtain a ratio; (7) Find the data points where the ratio is statistically less than 1 to identify shading points; (8) To quantify energy losses, subtract measured production data from weather-adjusted photovoltaic production data. Then, integrate over time for each of the identified shading data points.

More specifically, the method for determining and quantifying energy losses due to shading may be according to the steps of: calculating by a computer processor calibrated model parameters; calculating by a computer processor weather adjusted photovoltaic performance for at least one photovoltaic system; determining by a computer processor a set of data points for each photovoltaic system with photovoltaic system equipment mismatch; filtering out the set of data points for each photovoltaic system with photovoltaic system equipment mismatch by the computer processor; determining by a computer processor a subset of data points for each photovoltaic system with snow effects; filtering out the subset of data points for each photovoltaic system with snow effects by the computer processor; determining by a computer processor measured power and weather adjusted photovoltaic production data for each photovoltaic system; dividing by the computer processor the measured power for each photovoltaic system by the weather adjusted photovoltaic performance for each photovoltaic system to obtain a ratio data set having a set of ratios; determining by the computer processor a subset of the ratio data set having a set of ratios where the ratio is less than 1 to identify and provide shading data points; subtracting by the computer processor the measured power from the weather adjusted photovoltaic production data for each photovoltaic system to quantify energy losses; integrate the energy losses over time for each of the shading data points.

The present invention also provides methods for determining and quantifying energy losses due to soiling and equipment degradation. This approach identifies and quantifies losses due to soiling of photovoltaic panels and inherent physical degradation of installed equipment of a photovoltaic system, such as photovoltaic panels and inverters.

Definition of Variables. Performance test conditions (PTC)=generally considered to be E=1000 W/m², Tₐ=20° C., v=1 m/s. Standard test conditions (STC)=generally considered to be E=1000 W/m², T_{c}=25° C.

Generally, the methods for determining and quantifying energy losses due to soiling and equipment degradation may be according to the steps of: (1) Calculating calibrated model parameters (above, methods for calibrating photovoltaic model parameters to improve modeling accuracy of photovoltaic power production); (2) Using ASTM E2848-11 Standard Test Method for Reporting Photovoltaic Non-Concentrator System Performance as a guide, create a multivariable linear regression. The multiple linear regression follows the equation ?=E·(α₁+α₂·E+a₃·Tₐ+α₄·v) [(P=E·(a₁+a₂·E+a₃·Tₐ+a₄·v))] where E=plane of array irradiance (W/m²), P=modeled PV system power (W), Tₐ=ambient temperature (° C.), and v=wind speed (m/s) OR P=·(α₂+α₂˜E+α₃·Tₜ) [P=E·(a₁+a₂·E+a₃·T_{c})] where E=plane of array irradiance (W/m²), P=PV system power (W), and T_{c}, =cell temperature (° C.); (3) Using the a values found in step 2 through the regression, obtain a value for photovoltaic system capacity using performance test conditions (PTC) or standard test conditions (STC); (4) Repeat steps 2 and 3 to determine new photovoltaic capacities for subsequent time periods, which can be months or years. The difference between capacities is soiling and equipment degradation.

Production data could come from, without limitation, PV System (kW or kWh), Solar thermal system (kW or kWh), Concentrated solar power system (kW or kWh) and Wind turbine (kW or kWh). Sensor data could come from, without limitation, Pyranometer (W/m̂2 or Wh/m̂2), Pyrheliometer (W/m̂2 or Wh/m̂2), PV reference cell (W/m̂2 or Wh/m̂2), Radiometer (W/m̂2 or Wh/m̂2), Pyrgeometer (W/m̂2 or Wh/m̂2), Anemometer (mph or m/s). This type of data consists of a hardware measurement (units listed beside hardware) and a corresponding point in time or time interval, producing a time series of data (multiple time points and data). For example, monitored PV production data is measured every 5 minutes, resulting in a 1 day dataset containing 288 measurements and timestamp pairs.

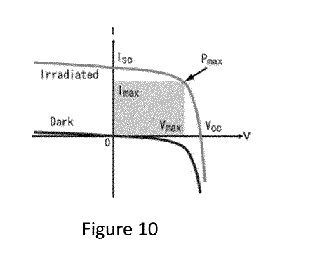

FIG. 10 shows the current-voltage characteristics of a solar cell at a particular light level, and in darkness. The area of the center rectangle gives the output power. Pmax denotes the maximum power point, where Pmax=Vmax*Imax.

The present invention provides important solutions for identifying and quantifying disaggregated photovoltaic performance losses; allows those responsible for photovoltaic systems to take corrective action for actionable issues causing losses by knowing disaggregated photovoltaic performance losses; allows photovoltaic design engineers to improve future designs by understanding historical losses and knowing disaggregated photovoltaic performance losses. For portfolio-wide analysis of many photovoltaic systems, understanding performance risks by types allows for lower uncertainty and opportunity to diversify certain types of manageable risks.

It should be understood that the foregoing relates to preferred embodiments of the invention and that modifications may be made without departing from the spirit and scope of the invention as set forth in the following claims.

We claim:

1. A computer processor implemented method of calibrating photovoltaic model parameters to improve modeling accuracy of photovoltaic power production, said method comprising the steps of:
obtaining in a computer processor environmental conditions representative of at least one photovoltaic system being analyzed;
obtaining in a computer processor measured power of each photovoltaic system being analyzed;
estimating by the computer processor a power output for each photovoltaic system being analyzed according to the environmental conditions representative of each photovoltaic system being analyzed to provide a modeled power;
comparing by the computer processor the modeled power and the measured power of each photovoltaic system being analyzed to provide a set of ratio data points;
filtering by the computer processor the set of ratio data points that are statistical outliers to provide a filtered set of ratio data points;
identifying by the computer processor a most statistically representative ratio for the filtered set of ratio data points to provide a calibrated modeled photovoltaic power production.

2. A method as in claim 1, wherein the environmental conditions are measured environmental conditions or modeled environmental conditions.

3. A method as in claim 1, wherein the most statistically representative ratio for the filtered set of ratio data points is taken as the model parameter correction factor.

4. A method as in claim 1, further comprising the step of estimating by the computer processor a photovoltaic production expectation for each photovoltaic system according to typical meteorogical year (TMY) data as an input.

5. A method as in claim 4, wherein the step of estimating by the computer processor a power output for the photovoltaic system is further according to measured environmental data as an input to provide weather adjusted photovoltaic performance.

6. A method as in claim 4, wherein the step of estimating by the computer processor a power output for each photovoltaic system is further according to modeled environmental data as an input to provide weather adjusted photovoltaic performance.

7. A computer implemented method of determining and quantifying energy losses due to equipment mismatch, said method comprising the steps of:
obtaining in a computer processor measured power of each photovoltaic system being analyzed;
sorting by a computer processor measured power for each photovoltaic system by power output to provide sorted measured power;
filtering the sorted measured power by discarding outlier values to provide filtered measured power;
obtaining in a computer processor a maximum power output for each photovoltaic system being analyzed;
obtaining in a computer processor environmental conditions representative of each photovoltaic system being analyzed;
estimating by the computer processor a power output for each photovoltaic system being analyzed according to the environmental conditions representative of each photovoltaic system being analyzed to provide a modeled power;
comparing by the computer processor the modeled power and the measured power of each photovoltaic system being analyzed to provide a set of ratio data points;
filtering by the computer processor the set of ratio data points that are statistical outliers to provide a filtered data set;
identifying by the computer processor a most statistically representative ratio for the filtered data set to provide a calibrated modeled photovoltaic power production;
recalculating by the computer processor a power output for each photovoltaic system further according to environmental data as an input to provide weather adjusted photovoltaic performance for the set of ratio data points;
determining a set of measured data points in which the measured power is equivalent to an inverter size;
subtracting the measured power from the modeled power to quantify power losses due to equipment mismatch; and
integrating the power losses due to equipment mismatch over a time period during which the measured power is equivalent to the inverter size.

8. A method as in claim 7, wherein the environmental data is selected from the group consisting of measured environmental data and modeled environmental data.

9. A method as in claim 7, wherein the outlier values are values that only occur once.

10. A method as in claim 7, wherein the outlier values are values that exceed a set outlier threshold.

11. A method as in claim 7, further comprising the step of: estimating by the computer processor a photovoltaic production expectation for each photovoltaic system according to typical metrological year (TMY) data as an input to provide TMY input.

12. A computer implemented method of determining and quantifying energy losses due to snow, said method comprising the steps of:
obtaining in a computer processor environmental conditions representative of at least one photovoltaic system being analyzed;
obtaining in a computer processor measured power of each photovoltaic system being analyzed;
estimating by the computer processor a power output for each photovoltaic system according to the environmental conditions representative of the photovoltaic system being analyzed to provide a modeled power;
comparing by the computer processor the modeled power and measured power of each photovoltaic system being analyzed to provide a set of ratio data points;
filtering by the computer processor the set of ratio data points that are statistical outliers;
identifying by the computer processor a most statistically representative ratio for the data set to provide a calibrated modeled photovoltaic power production;
recalculating by the computer processor a power output for each photovoltaic system further according to environmental data as an input to provide weather adjusted photovoltaic performance for the set of ratio data points;
obtaining in a computer processor measured power and expected typical performance production data;
determining a set of time periods from the set of ratio data points where measured power is statistically small compared to expected typical performance production data to provide a set of questioned time periods;
verifying snow conditions for the set of questioned time periods to provide a set of verified questioned time periods;
subtracting measured power from weather adjusted photovoltaic performance for the set of verified questioned time periods to quantify energy losses due to snow; and
integrating the losses due to snow over the verified questions time periods.

13. A method as in claim 12, wherein the environmental data is selected from the group consisting of measured environmental data and modeled environmental data.

14. A method as in claim 12, wherein the outlier values are values that only occur once.

15. A method as in claim 12, wherein the outlier values are values that exceed a set outlier threshold.

16. A method as in claim 12, further comprising the step of:
estimating by the computer processor a photovoltaic production expectation for each photovoltaic system according to typical meteorological year (TMY) data as an input to provide TMY input;
recalculating by the computer processor a power output for each photovoltaic system further according to TMY input to provide photovoltaic production expectations for the lifetime of the photovoltaic system.

17. A computer implemented method of determining and quantifying energy losses due to snow, said method comprising the steps of:
obtaining in a computer processor environmental conditions representative of at least one photovoltaic system being analyzed;
obtaining in a computer processor measured power of each photovoltaic system being analyzed;
estimating by the computer processor a power output for each photovoltaic system according to the environmental conditions representative of a photovoltaic system being analyzed to provide a modeled power;
comparing by the computer processor the modeled power and measured power of each photovoltaic system being analyzed to provide a set of ratio data points;
filtering by the computer processor the set of ratio data points that are statistical outliers;
identifying by the computer processor a most statistically representative ratio for the data set to provide a calibrated modeled photovoltaic power production;
recalculating by the computer processor a power output for each photovoltaic system further according to environmental data as an input to provide weather adjusted photovoltaic performance for the set of ratio data points;
obtaining in a computer processor expected typical performance production data for each photovoltaic system;
determining a set of time periods from the set of ratio data points where weather adjusted photovoltaic performance is statistically small compared to expected typical performance production data to provide a set of questioned time periods;
verifying snow conditions for the set of questioned time periods to provide a set of verified questioned time periods;
interpolating between adjacent measured production for the set of ratio data points to the set of data points to provide estimated power for that time;
subtracting measured power from estimated power to obtain an estimated power difference; and
integrating the estimated power difference over the verified questioned time periods.

18. A method as in claim 17, wherein the environmental data is selected from the group consisting of measured environmental data and modeled environmental data.

19. A method as in claim 17, wherein the outlier values are values that only occur once.

20. A method as in claim 17, wherein the outlier values are values that exceed a set outlier threshold.

21. A method as in claim 17, further comprising the step of:
estimating by the computer processor a photovoltaic production expectation for each photovoltaic system according to typical meteorological year (TMY) data as an input to provide TMY input;
recalculating by the computer processor a power output for each photovoltaic system further according to TMY input to provide photovoltaic production expectations for the lifetime of the photovoltaic system.

22. A computer implemented method of determining and quantifying energy losses due to equipment downtime, said method comprising the steps of:
obtaining in a computer processor sunrise and sunset for each day of measured production being analyzed for at least one photovoltaic system being analyzed;
determining in a computer processor a time after sunrise for each photovoltaic system being analyzed when a measured data is consistently positive to provide a sunrise point for each day;
ignoring all zero or negative values after the sunrise point for each day;
determining in a computer processor a time before sunset for each photovoltaic system being analyzed when a measured data is not consistently negative to provide a sunset point for each day;
ignoring all zero or negative values before the sunset point for each day;
determining a set of data points for which measured data is zero or negative between the sunrise point and sunset point;
obtaining in a computer processor environmental conditions representative of each photovoltaic system being analyzed;
obtaining in a computer processor measured power of each photovoltaic system being analyzed;
estimating by the computer processor a power output for each photovoltaic system according to the environmental conditions representative of a photovoltaic system being analyzed to provide a modeled power;
comparing by the computer processor the modeled power and the measured power of each photovoltaic system being analyzed to provide a set of ratio data points;
filtering by the computer processor the set of ratio data points that are statistical outliers;
identifying by the computer processor a most statistically representative ratio for the data set to provide a calibrated modeled photovoltaic power production;
recalculating by the computer processor a power output for each photovoltaic system further according to environmental data as an input to provide weather adjusted photovoltaic performance for the set of ratio data points;
subtracting the measured power from the weather adjusted photovoltaic performance to provide an estimated power difference for that time; and
integrating the estimated power difference for that time for a set of data points for which measured data is zero or negative between the sunrise point and sunset point.

23. A method as in claim 22, wherein the environmental data is selected from the group consisting of measured environmental data and modeled environmental data.

24. A method as in claim 22, wherein said outlier values are values that only occur once.

25. A method as in claim 22, wherein said outlier values are values that exceed a set outlier threshold.

26. A method as in claim 22, further comprising the steps of:
estimating by the computer processor a photovoltaic production expectation for the photovoltaic system according to typical meteorological year (TMY) data as an input;

27. A computer implemented method of determining and quantifying energy losses due to equipment downtime, said method comprising the steps of:
obtaining in a computer processor sunrise and sunset for each day of measured production being analyzed for each photovoltaic system being analyzed;
determining in a computer processor a time after sunrise for each photovoltaic system being analyzed when the measured data is consistently positive to provide a sunrise point for each day;
ignoring all zero or negative values before the sunrise point for each day;
determining in a computer processor a time before sunset for each photovoltaic system being analyzed when the measured data is not consistently negative to provide a sunset point for each day;
ignoring all zero or negative values after the sunset point for each day;
determining a set of data points for which measured data is zero or negative between the sunrise point and sunset point;
obtaining in a computer processor environmental conditions representative of a photovoltaic system being analyzed;
obtaining in a computer processor measured power of each photovoltaic system being analyzed;
estimating by the computer processor a power output for each photovoltaic system according to the environmental conditions representative of each photovoltaic system being analyzed to provide a modeled power;
comparing by the computer processor the modeled power and measured power of each photovoltaic system being analyzed to provide a set of ratio data points;
filtering by the computer processor the set of ratio data points that are statistical outliers;
identifying by the computer processor a most statistically representative ratio for the data set to provide a calibrated modeled photovoltaic power production;
recalculating by the computer processor a power output for each photovoltaic system further according to environmental data as an input to provide weather adjusted photovoltaic performance for the set of ratio data points;
interpolating between adjacent measured production for the set of ratio data points to the set of data points to provide estimated power for that time;
subtracting the measured power from the estimated power to obtain an estimated power difference; and
integrating the estimated power difference for that time for a set of data points for which measured data is zero or negative between the sunrise point and sunset point.

28. A method as in claim 27, wherein the environmental data is selected from the group consisting of measured environmental data and modeled environmental data.

29. A method as in claim 27, wherein said outlier values are values that only occur once.

30. A method as in claim 27, wherein said outlier values are values that exceed a set outlier threshold.

31. A method as in claim 27, further comprising the steps of: estimating by the computer processor a photovoltaic production expectation for the photovoltaic system according to typical meteorological year (TMY) data as an input;

32. A computer implemented method for determining and quantifying energy losses due to shading, said method comprising the steps of:
calculating by a computer processor calibrated model parameters;
calculating by a computer processor weather adjusted photovoltaic performance for at least one photovoltaic system;
determining by a computer processor a set of data points for each photovoltaic system with photovoltaic system equipment mismatch;
filtering out the set of data points for each photovoltaic system with photovoltaic system equipment mismatch by the computer processor;
determining by a computer processor a subset of data points for each photovoltaic system with snow effects;
filtering out the subset of data points for each photovoltaic system with snow effects by the computer processor;
determining by a computer processor measured power and weather adjusted photovoltaic production data for each photovoltaic system;
dividing by the computer processor the measured power for each photovoltaic system by the weather adjusted photovoltaic performance for each photovoltaic system to obtain a ratio data set having a set of ratios;
determining by the computer processor a subset of the ratio data set having a set of ratios where the ratio is less than 1 to identify and provide shading data points;
subtracting by the computer processor the measured power from the weather adjusted photovoltaic production data for each photovoltaic system to quantify energy losses;
integrate the energy losses over time for each of the shading data points.

33. A method as in claim 32, wherein the step of calculating by a computer processor calibrated model parameters is according to the steps of:
obtaining in a computer processor environmental conditions representative of at least one photovoltaic system being analyzed;
obtaining in a computer processor measured power of each photovoltaic system being analyzed;
estimating by the computer processor a power output for each photovoltaic system according to the environmental conditions representative of at least one photovoltaic system being analyzed to provide a modeled power;
comparing by the computer processor the modeled power and the measured power of each photovoltaic system being analyzed to provide a set of ratio data points;
filtering by the computer processor the set of ratio data points that are statistical outliers;
identifying by the computer processor a most statistically representative ratio for the set of ratio data points to provide a calibrated modeled photovoltaic power production.

34. A method as in claim 27, wherein the step of calculating by a computer processor weather adjusted photovoltaic performance for each photovoltaic system is according to the steps of:
obtaining in a computer processor environmental conditions representative of at least one photovoltaic system being analyzed;
obtaining in a computer processor measured power of each photovoltaic system being analyzed;
estimating by the computer processor a power output for each photovoltaic system according to the environmental conditions representative of at least one photovoltaic system being analyzed to provide a modeled power;
comparing by the computer processor the modeled power and the measured power of each photovoltaic system being analyzed to provide a set of ratio data points;
filtering by the computer processor the set of ratio data points that are statistical outliers;
identifying by the computer processor a most statistically representative ratio for the data set to provide a calibrated modeled photovoltaic power production, wherein the step of estimating by the computer processor a power output for each photovoltaic system is further according to environmental data as an input to provide weather adjusted photovoltaic performance.

35. A method of determining and quantifying energy losses due to soiling and equipment degradation, said method comprising the steps of:
calculating by a computer processor calibrated model parameters for at least one photovoltaic system;
determining by a computer processor a modeled photovoltaic system power using a multivariable linear regression;
determining a value for each photovoltaic system capacity by the computer processor using test conditions;
iteratively repeating the steps of:
determining by a computer processor a modeled photovoltaic system power using a multivariable linear regression; and
determining a value for photovoltaic system capacity by the computer processor using test conditions, to determine new photovoltaic capacities for subsequent time periods.

36. A method as in claim 35, wherein the multivariable linear regression follow the equation:
P=E·(α₁+α₂·E+α₃·T_{α}+α₄·ν)
where E=plane of array irradiance (W/m²), P=modeled PV system power (W), Tₐ=ambient temperature (° C.), and v=wind speed (m/s).

37. A method as in claim 35, wherein the multivariable linear regression follow the equation:
P=E·(α₁+α₂·E+α₃·T_{c})
where E=plane of array irradiance (W/m²), P=PV system power (W), and T_{c}=cell temperature (° C.).

38. A method as in claim 35, wherein said test conditions are performance test conditions (PTC).

39. A method as in claim 35, wherein said test conditions are standard test conditions (STC).
